(19) United States
(12) Patent Application Publication
(10) Pub. No.: US 2025/0384938 A1
(43) Pub. Date: Dec. 18, 2025

(54) MEMORY DEVICE AND METHOD OF OPERATING THE MEMORY DEVICE

(71) Applicant: SK hynix Inc., Icheon-si Gyeonggi-do (KR)

(72) Inventor: Eun Young PARK, Icheon-si Gyeonggi-do (KR)

(73) Assignee: SK hynix Inc., Icheon-si Gyeonggi-do (KR)

(21) Appl. No.: 19/065,643

(22) Filed: Feb. 27, 2025

(30) Foreign Application Priority Data
Jun. 12, 2024 (KR) 10-2024-0076397

(51) Int. Cl. G11C 16/34; G11C 16/12; G11C 16/32

(52) U.S. Cl. CPC G11C 16/3459; G11C 16/12; G11C 16/32

(57) ABSTRACT

Provided herein is a memory device and a method of operating the memory device. The memory device including a memory block connected to bit lines and a source line, a peripheral circuit configured to perform a program operation on the memory block, and a control circuit configured to control the peripheral circuit to perform the program operation on the memory block in response to a program command, control the peripheral circuit to suspend the program operation and perform a suspend operation in response to a suspend command, and control the peripheral circuit to resume the suspended program operation in response to a resume command, wherein the control circuit is configured to change verify levels corresponding to program states based on the suspend operation.

### CROSS-REFERENCE TO RELATED APPLICATION

The present application claims priority under 35 U.S.C. § 119 (a) to Korean patent application number 10-2024-0076397 filed on Jun. 12, 2024, in the Korean Intellectual Property Office, the entire contents of which application is incorporated herein by reference.

### BACKGROUND

### 1. Technical Field

Various embodiments of the present disclosure generally relate to a memory device and a method of operating the memory device, and more particularly to a memory device and a method of operating the memory device, which are configured to perform a program operation.

### 2. Related Art

A memory device includes a memory block in which data is stored.

The memory device may perform erase, program, and read operations on the memory block under the control of a controller.

While a program operation is being performed in the memory device, the controller may transmit a suspend command to the memory device. The suspend command may be a command for temporarily suspending the operation being performed in the memory device and performing an operation corresponding to another command. When a suspend operation corresponding to the suspend command is completed, the controller may transmit a resume command for resuming the suspended program operation in the memory device to the memory device.

While the suspend operation is being performed, the previously performed program operation is suspended, and the suspended program operation is resumed when the suspend operation is completed. Accordingly, the threshold voltages of memory cells may be changed depending on the suspend operation and the time at which the program operation is resumed.

### SUMMARY

An embodiment of the present disclosure may provide for a memory device. The memory device may include a memory block connected to bit lines and a source line, a peripheral circuit configured to perform a program operation on the memory block, and a control circuit configured to control the peripheral circuit to perform the program operation on the memory block in response to a program command, control the peripheral circuit to suspend the program operation and perform a suspend operation in response to a suspend command, and control the peripheral circuit to resume the suspended program operation in response to a resume command, wherein the control circuit is configured to change verify levels corresponding to program states based on the suspend operation.

An embodiment of the present disclosure may provide for a method of operating a memory device. The method may include performing a program operation on a memory block, when a suspend command is input while the program operation is being performed, suspending the program operation and performing a suspend operation, when a resume command is input after the suspend operation is completed, setting verify levels corresponding to program states of the program operation depending on a number of times the suspend operation is performed, and resuming the program operation using the set verify levels.

An embodiment of the present disclosure may provide for a method of operating a memory device. The method may include performing a program operation on a memory block, when a first suspend command is input while the program operation is being performed, suspending the program operation and performing a first suspend operation, when a first resume command is input after the first suspend operation is completed, resuming the program operation, when a second suspend command is input while the program operation is being performed, suspending the program operation and performing a second suspend operation, when a second resume command is input after the second suspend operation is completed, setting verify levels corresponding to program states of the program operation depending on a duration of time beginning from input of the first resume command and ending with input of the second suspend command, and resuming the program operation using the set verify levels.

An embodiment of the present disclosure may provide for a method of operating a memory device. The method may include performing a program operation on a memory block, when a suspend command is input while the program operation is being performed, suspending the program operation and performing a suspend operation, when a resume command is input after the suspend operation is completed, setting verify levels corresponding to program states of the program operation depending on a duration of time beginning from start of the program operation and ending with input of the suspend command, and resuming the program operation using the set verify levels.

An embodiment of the present disclosure may provide for a method of operating a memory device. The method may include performing a program operation on a memory block, when a first suspend command is input while the program operation is being performed, suspending the program operation and performing a first suspend operation, when a first resume command is input after the first suspend operation is completed, resuming the program operation, when a second suspend command is input while the program operation is being performed, suspending the program operation and performing a second suspend operation, when a second resume command is input after the second suspend operation is completed, setting verify levels corresponding to program states of the program operation depending on a duration of first time beginning from input of the first resume command and ending with input of the second suspend command and a duration of third time beginning from input of the first suspend command and ending with input of the second resume command, and resuming the program operation using the set verify levels.

An embodiment of the present disclosure may provide for a method of operating a memory device. The method may include performing a program operation on a memory block, when a suspend command is input while the program operation is being performed, suspending the program operation and performing a suspend operation, when a resume command is input after the suspend operation is completed, setting verify levels corresponding to program states of the program operation depending on a duration of time beginning from start of the program operation and ending with input of the suspend command and a number of times the suspend operation is performed, and resuming the program operation using the set verify levels.

### BRIEF DESCRIPTION OF THE DRAWINGS

FIG. 1 is a diagram illustrating an embodiment of a memory system.

FIG. 2 is a diagram illustrating an embodiment of a memory device.

FIG. 3 is a circuit diagram illustrating an embodiment of a memory block.

FIG. 4 is a diagram illustrating the case where the threshold voltage distributions of memory cells are changed for an embodiment.

FIG. 5 is a flowchart illustrating a method of operating a memory device according to a first embodiment of the present disclosure.

FIGS. 6A, 6B, 6C, and 6D are diagrams illustrating methods of changing verify levels according to the first embodiment.

FIG. 7 is a flowchart illustrating a method of operating a memory device according to a second embodiment of the present disclosure.

FIG. 8 is a flowchart illustrating a method of operating a memory device according to a third embodiment of the present disclosure.

FIGS. 9A and 9B are diagrams illustrating methods of changing verify levels according to the third embodiment.

FIG. 10 is a flowchart illustrating a method of operating a memory device according to a fourth embodiment of the present disclosure.

FIG. 11 is a flowchart illustrating a method of operating a memory device according to a fifth embodiment of the present disclosure.

FIG. 12 is a diagram illustrating a method of changing a verify level according to first to fifth embodiments of the present disclosure.

FIG. 13 is a diagram illustrating a memory card system to which a memory system according to an embodiment of the present disclosure is applied.

FIG. 14 is a diagram illustrating a solid state drive (SSD) system to which a memory device according to an embodiment of the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, although the terms “first” and “second” may be used herein to describe various elements, these elements should not be limited by these terms. The terms are used to distinguish one element from other elements.

Various embodiments of the present disclosure are directed to a memory device, which can prevent or mitigate the reliability of the memory device from deteriorating due to the degradation of the memory device.

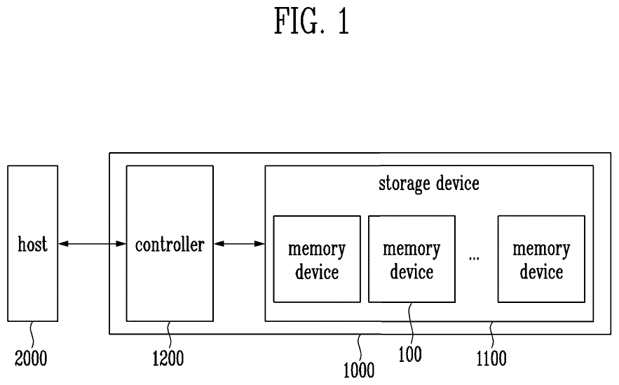

FIG. 1 is a diagram illustrating an embodiment of a memory system.

Referring to FIG. 1, a memory system 1000 may include a storage device 1100 and a controller 1200.

The storage device 1100 may include a plurality of memory devices 100 which store data. Each of the memory devices 100 may be implemented using a volatile memory device or a nonvolatile memory device. The volatile memory device may be a device may be a device in which stored data is lost when power supply is interrupted. The nonvolatile memory device may be a device may be a device in which stored data is retained even when power supply is interrupted.

The controller 1200 may perform communication between a host 2000 and the storage device 1100. The controller 1200 may control the storage device 1100 in response to a request received from the host 2000. The controller 1200 may transmit voltages that are used in program, read, and erase operations, and parameters including voltage application time or the like to each memory device 100.

The host 2000 may communicate with the storage device 1100 through the controller 1200 using an interface protocol such as peripheral component interconnect-express (PCI-E), advanced technology attachment (ATA), serial ATA (SATA), parallel ATA (PATA), or serial attached SCSI (SAS). Interface protocols between the host 2000 and the memory system 1000 are not limited to the above-described examples, and may include various interfaces, such as a universal serial bus (USB), a multi-media card (MMC), an enhanced small disk interface (ESDI), or integrated drive electronics (IDE).

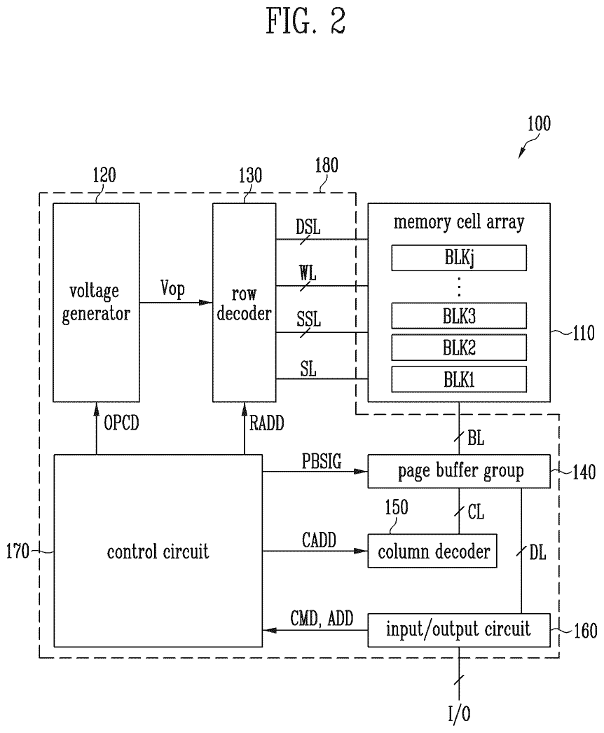

FIG. 2 is a diagram illustrating an embodiment of a memory device.

Referring to FIG. 2, the memory device 100 may include a memory cell array 110 in which data is stored, a peripheral circuit 180 which performs a program operation, a read operation or an erase operation, and a control circuit 170 which controls the peripheral circuit 180.

The memory cell array 110 may include first to j-th memory blocks BLK1 to BLKj in which data is stored. Each of the first to j-th memory blocks BLK1 to BLKj may include a plurality of memory cells, which may be implemented in a two-dimensional (2D) structure in which the memory cells are arranged horizontally on a substrate or in a three-dimensional (3D) structure in which the memory cells are stacked vertically on a substrate. Each of the first to j-th memory blocks BLK1 to BLKj according to an embodiment may be formed in a 3D structure.

The peripheral circuit 180 may include a voltage generator 120, a row decoder 130, a page buffer group 140, a column decoder 150, and an input/output circuit 160.

The voltage generator 120 may generate and output operating voltages Vop required for various operations in response to operation code OPCD. For example, the voltage generator 120 may generate and output a program voltage, a verify voltage, a read voltage, a pass voltage, an erase voltage, a compensation voltage, etc. The voltage generator 120 may adjust respective output times of the voltages included in the operating voltages Vop in response to the operation code OPCD.

The row decoder 130 may select one memory block from among the first to j-th memory blocks BLK1 to BLKj included in the memory cell array 110 according to a row address RADD, and may transmit the operating voltages Vop to the selected memory block.

The page buffer group 140 may be connected to the memory cell array 110 through bit lines. For example, the page buffer group 140 may include page buffers connected to the bit lines, respectively. The page buffers may be simultaneously operated in response to page buffer control signals PBSIG, and may store data during a program or read operation. For this operation, each of the page buffers may include a plurality of latches in which data is stored. The number of latches may vary depending on a program method. For example, the page buffers may be designed differently depending on the number of bits that can be stored in one memory cell, and may be designed differently depending on the number of verify voltages used in a verify operation.

The column decoder 150 may transfer data between the input/output circuit 160 and the page buffer group 140 according to a column address CADD.

The input/output circuit 160 may be connected to a controller 1200 through input/output lines (I/O). The input/output circuit 160 may receive or output a command CMD, an address ADD, and data DATA through the input/output lines (I/O). For example, the input/output circuit 160 may transmit the command CMD and the address ADD, received through the input/output lines (I/O), to the control circuit 170, and may transmit the data, received through the input/output lines (I/O), to the column decoder 150. The input/output circuit 160 may output the data DATA, received from the column decoder 150, to an external device through the input/output lines (I/O).

The control circuit 170 may output the operation code OPCD, the row address RADD, the page buffer control signals PBSIG, and the column address CADD in response to the command CMD and the address ADD. For example, the control circuit 170 may control the peripheral circuit 180 to perform a program operation on a selected memory block in response to a program command. The control circuit 170 may suspend (i.e., halt or interrupt) the program operation being performed on the selected memory block and perform a suspend operation in response to a suspend command. The suspend operation may be an operation selected from among program, read, and erase operations. The control circuit 170 may resume the suspended program operation in response to a resume command.

The control circuit 170 may change the verify level of the program operation depending on the number of suspend operations. The control circuit 170 may change the verify level of the program operation depending on the time at which the suspend command is input and the time at which the resume command is input. The verify level may be changed by the verify voltage applied to a selected word line and by the voltage applied to at least one of the bit lines connected to the selected memory block and the source line connected to the selected memory block.

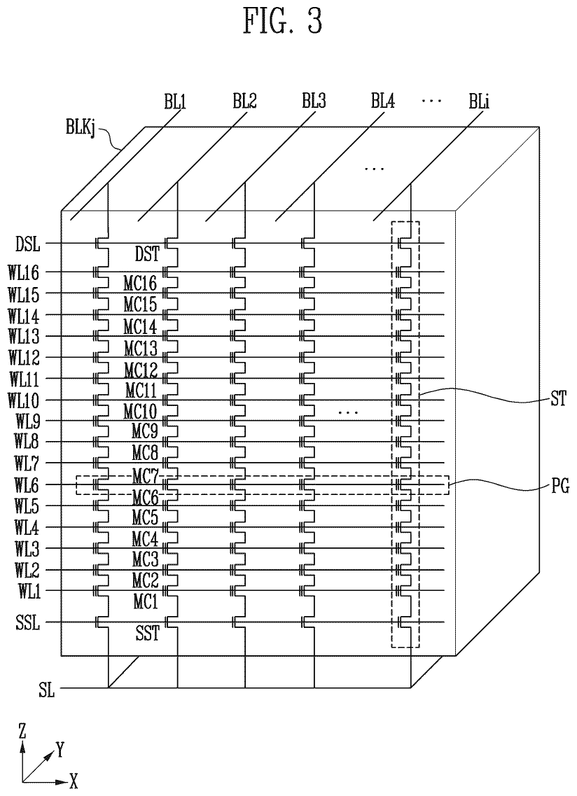

FIG. 3 is a circuit diagram illustrating an embodiment of a memory block.

Referring to FIG. 3, the j-th memory block BLKj, which is any one of the first to j-th memory blocks BLK1 to BLKj, shown in FIG. 2, is illustrated by way of example.

The j-th memory block BLKj may include cell strings ST disposed between the source line SL and first to i-th bit lines BL1 to BLi. The cell strings ST may be arranged to be spaced apart from each other along X and Y directions, and each of the cell strings ST may extend in a Z direction. The first to i-th bit lines BL1 to BLi may be arranged to be spaced apart from each other along the X direction, and each of the first to i-th bit lines BL1 to BLi may extend along the Y direction. FIG. 3 is a diagram illustrating an embodiment of the j-th memory block BLKj, and thus the numbers of source select transistors SST, first to sixteenth memory cells MC1 to MC16, and drain select transistors DST, which are included in each of the cell strings ST, may vary depending on the memory device.

Gates of source select transistors SST included in different cell strings ST may be connected to a source select line SSL, gates of the first to sixteenth memory cells MC1 to MC16 may be connected to first to sixteenth word lines WL1 to WL16, and gates of drain select transistors DST may be connected to a drain select line DSL. The source select line SSL may be connected in common to the source select transistors SST arranged along the X and Y directions. Alternatively, a source select line SSL connected in common to the source select transistors SST arranged in the X direction and a source select line SSL connected in common to the source select transistors SST arranged in the Y direction may be separated from each other. The first to sixteenth word lines WL1 to WL16 may be connected in common to the memory cells arranged along the X and Y directions. For example, the first memory cells MC1 arranged along the X and Y directions may be connected in common to the first word line WL1, and the second memory cells MC2 arranged along the X and Y directions may be connected in common to the second word line WL2. The drain select line DSL may be connected in common to the drain select transistors DST arranged in the X direction. Different drain select lines DSL may be connected to the drain select transistors DST arranged in the Y direction.

A group of memory cells connected to the same word line may be a page (PG). A program or read operation may be performed on a page (PG) basis. For example, a group of memory cells connected to a selected word line among memory cells of the cell strings ST connected to a drain select line DSL, selected from among the drain select lines DSL, may be a selected page. The selected page may be a page composed of program target memory cells during a program operation. That is, the selected page may be determined by the drain select lines DSL and the corresponding word line.

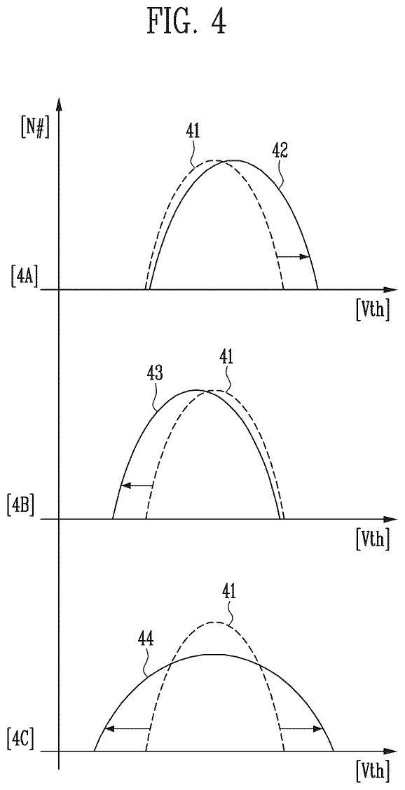

FIG. 4 is a diagram illustrating the case where the threshold voltage distributions of memory cells are changed for an embodiment.

Referring to FIG. 4, the threshold voltage distributions of the memory cells may be changed as the number of times cycling occurs on a memory block (i.e., cycling count) increases. Cycling may increase whenever an erase operation and a program operation are performed on the memory block. Therefore, the increase in the cycling count of the memory block may mean that the number of operations performed on the memory block increases. As the number of operations performed on the memory block increases, memory cells included in the memory block are subjected to more electrical stress, and thus electrical characteristics of the memory cells may be degraded. For example, as the cycling count increases, the number of electrons trapped in a tunnel isolation layer of each memory cell may increase, thus changing the band gap of the memory cell. The band gap of the memory cell may affect the movement of electrons during program and read operations on the memory cell. Therefore, as the cycling count of the memory block increases, the threshold voltage distributions of the memory cells included in the memory block may be widened (42, 43, and 44) compared to an initial distribution 41 depending on the electrical characteristics of the memory cells. ‘Vth’ illustrated in FIG. 4 denotes voltage, and ‘N #’ denotes the number of memory cells. The threshold voltages of memory cells distributed at a relatively high voltage in the threshold voltage distribution may further increase (42), the threshold voltages of memory cells distributed at a relatively low voltage in the threshold voltage distribution may further decrease (43), or the threshold voltages of memory cells distributed at a relatively high voltage may further increase and the threshold voltages of memory cells distributed at a relatively low voltage may further decrease (44).

Such a change in threshold voltage distribution may also affect a resume operation after the suspension of the memory device. For example, when a suspend command is input to the memory device while a program operation is being performed in the memory device, the memory device may suspend the program operation and perform a suspend operation in response to the suspend command. The suspend operation may be a program operation, a read operation or an erase operation. When a resume command is input after the suspend operation has been completed, the memory device may perform the suspended program operation. In this case, the threshold voltages of the memory cells may be changed depending on the number of times the suspend operation is performed, the time from the input of the resume command to the input of a next suspend command, and the time from the input of the suspend command to the input of the resume command. Such threshold voltage changes may further increase as the cycling count increases.

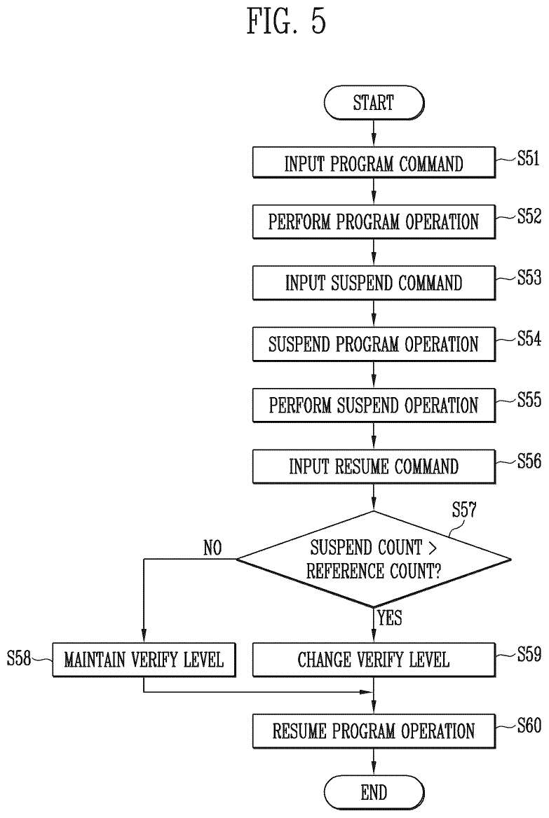

FIG. 5 is a flowchart illustrating a method of operating a memory device according to a first embodiment of the present disclosure.

Referring to FIG. 5, when a program command is input to the memory device at S51, the memory device (e.g., 100 of FIG. 2) may perform a program operation on a selected memory block at S52. For example, the controller (e.g., 1200 of FIG. 1) may output the program command, an address, and data to the memory device 100. The memory device 100 to which the program command, the address, and data output from the controller 1200 are input may select a memory block according to the address, and may program data to the selected memory block in response to the program command.

When a suspend command is input to the memory device 100 while the program operation is being performed on the selected memory block at S53, the memory device 100 may suspend the program operation being performed at S54, and may perform a suspend operation at S55. For example, the controller 1200 may output the suspend command to the memory device 100, and may then additionally output a command corresponding to the suspend operation. The suspend operation may be a program operation, a read operation or an erase operation.

When a resume command is input after the suspend operation is terminated at S56, the control circuit (e.g., 170 of FIG. 2) of the memory device 100 may compare a suspend count (i.e., the number of times the suspend operation is performed) with a reference count at S57. For example, the control circuit 170 may determine whether the suspend count is greater than the reference count. The suspend count may be determined to be the number of suspend commands input to the memory device 100. Therefore, the control circuit 170 may count the number of input suspend commands whenever the suspend command is input.

When the suspend count is less than the reference count (in the case of “No”), the control circuit 170 may maintain a preset verify level at S58. The verify level may refer to a criterion used to determine whether programming on the memory cells is completed during a verify operation performed in the program operation. For example, the verify level may be changed by at least one of a verify voltage applied to a selected word line, a bit line voltage applied to bit lines of the selected memory block, and a source line voltage applied to a source line. The word “preset” as used herein with respect to a parameter, such as a preset verify level or preset level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

At S57, when the suspend count is greater than the reference count (in the case of “Yes”), the control circuit 170 may change the verify level at S59. For example, the verify level may be changed when at least one of the verify voltage applied to the selected word line, the bit line voltage applied to the bit lines, and the source line voltage applied to the source line is adjusted.

When the suspend count is equal to the reference count at S57, the control circuit 170 may be set to perform any one of S58 and S59.

When the verify level is set at S58 or S59, the memory device 100 may resume the suspended program operation at S60 (i.e., resume program operation).

In the above-described first embodiment, the reason for changing the verify level depending on the suspend count is described as follows.

The increase in the suspend count may mean that the number of times the program operation is suspended and resumed in the memory device increases. Whenever the suspended program operation is resumed, the number of reprogrammed pages may increase. The verify level of the memory cells included in each reprogrammed page may increase or decrease depending on the target level. Here, the target level may refer to a final state to which the memory cells are programmed. For example, in the case of a triple-level cell (TLC) scheme in which 3 bits of data are stored in one memory cell, the corresponding memory cell may be maintained in an erase state or may be programmed to any one of seven different program states. In this case, the voltage level of the corresponding memory cell to have threshold voltages corresponding to the seven different program states may be the target level. Therefore, the target level may vary depending on the program state of each memory cell to be programmed.

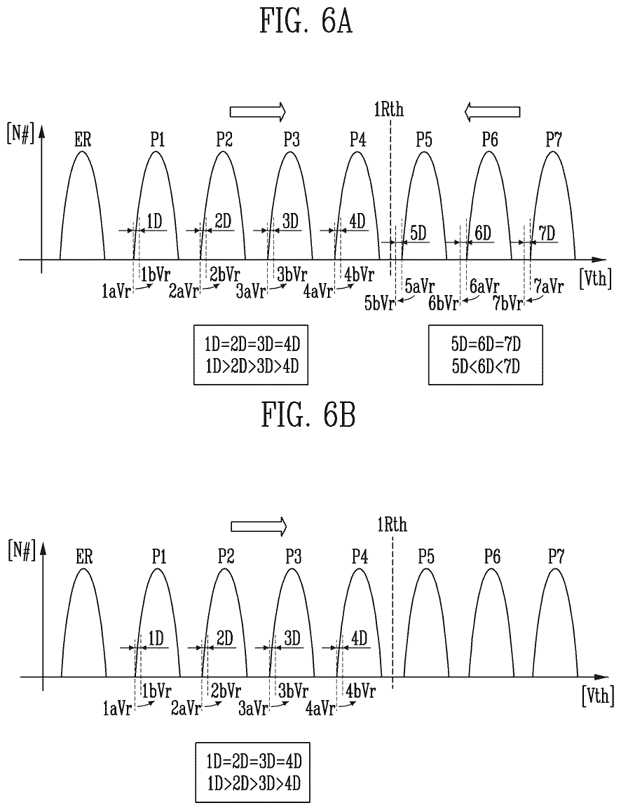

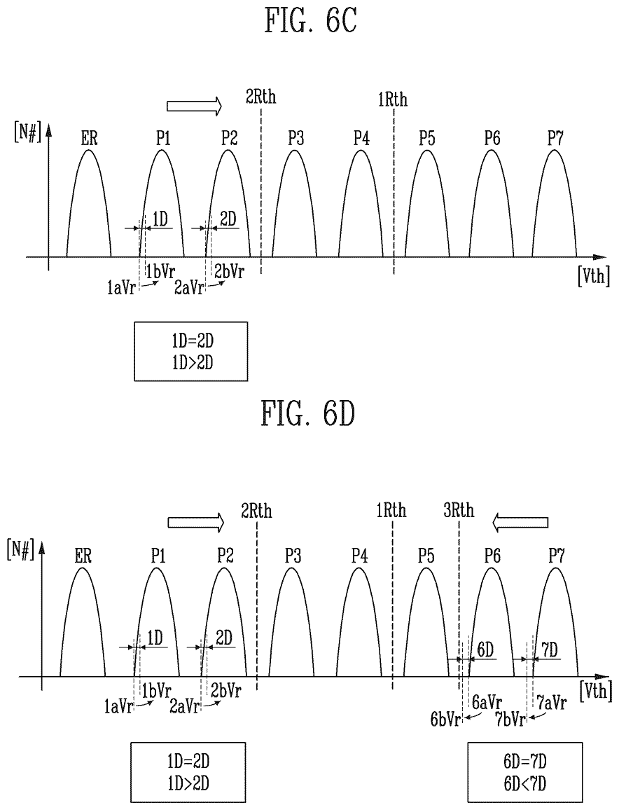

A detailed method of changing the verify level in the first embodiment will be described below with reference to FIGS. 6A to 6D.

FIGS. 6A to 6D are diagrams illustrating methods of changing verify levels according to the first embodiment.

Although, in FIGS. 6A to 6D, threshold voltage distributions in a triple-level cell (TLC) scheme are illustrated by way of example, the present embodiment may be applied to schemes other than the triple-level cell (TLC) scheme. In the triple-level cell (TLC) scheme, memory cells may be programmed to an erase state ER or any one of first to seventh program states P1 to P7.

Referring to FIG. 6A, as the suspend count increases, the number of reprogrammed pages may increase. Due thereto, as the threshold voltage is higher, the verify level may increase, whereas as the threshold voltage is lower, the verify level may decrease. In order to compensate for the change in verify level, the verify level may increase in program states P1 to P4 lower than a first reference voltage 1Rth, and may decrease in program states P5 to P7 higher than the first reference voltage 1Rth.

For example, a 1a-th verify level 1aVr in the first program state P1 lower than the first reference voltage 1Rth may be set higher to a 1b-th verify level 1bVr, a 2a-th verify level 2aVr in the second program state P2 may be set higher to a 2b-th verify level 2bVr, a 3a-th verify level 3aVr in the third program state P3 may be set higher to a 3b-th verify level 3bVr, and a 4a-th verify level 4aVr in the fourth program state P4 may be set higher to a 4b-th verify level 4bVr.

A 5a-th verify level 5aVr in the fifth program state P5 higher than the first reference voltage 1Rth may be set lower to a 5b-th verify level 5bVr, a 6a-th verify level 6aVr may be set lower to a 6b-th verify level 6bVr, and a 7a-th verify level 7aVr may be set lower to a 7b-th verify level 7bVr.

The variable range of the verify levels may be set within a range lower than ½ of the threshold voltage in each of the program states. For example, the 1b-th verify level 1bVr may be set within a range that is higher than the 1a-th verify level 1aVr and lower than ½ of the threshold voltage in the first program state P1.

The variable widths of respective verify levels in the program states may be equal to or different from each other. For example, the 1a-th verify level 1aVr and the 1b-th verify level 1bVr may have a first level difference 1D, the 2a-th verify level 2aVr and 2b-th verify level 2bVr may have a second level difference 2D, the 3a-th verify level 3aVr and the 3b-th verify level 3bVr may have a third level difference 3D, and the 4a-th verify level 4aVr and the 4b-th verify level 4bVr may have a fourth level difference 4D. The 5a-th verify level 5aVr and the 5b-th verify level 5bVr may have a fifth level difference 5D, the 6a-th verify level 6aVr and the 6b-th verify level 6bVr may have a sixth level difference 6D, and the 7a-th verify level 7aVr and the 7b-th verify level 7bVr may have a seventh level difference 7D. Respective level differences of the program states P1 to P7 may be calculated as values obtained by subtracting low verify levels from relatively high verify levels. For example, the first level difference 1D may be a value obtained by subtracting the 1a-th verify level 1aVr from the 1b-th verify level 1bVr, and the seventh level difference 7D may be a value obtained by subtracting the 7b-th verify level 7bVr from the 7a-th verify level 7aVr.

The first to seventh level differences 1D to 7D may be set equal to each other, or may be different from each other with respect to the first reference voltage 1Rth. For example, the first to fourth level differences 1D to 4D of the first to fourth program states P1 to P4 lower than the first reference voltage 1Rth may be equal to each other (1D=2D=3D=4D), the fifth to seventh level differences 5D to 7D of the fifth to seventh program states P5 to P7 higher than the first reference voltage 1Rth may be equal to each other (5D=6D=7D), and the first to fourth level differences 1D to 4D and the fifth to seventh level differences 5D to 7D may be different from each other.

Alternatively, in the program states P1 to P4 lower than the first reference voltage 1Rth, as the program states are lower, the level differences may increase, and in the program states P5 to P7 higher than the first reference voltage 1Rth, as the program states are higher, the level differences may increase. For example, in the program states P1 to P4 lower than the first reference voltage 1Rth, the first level difference 1D may be the highest, the second level difference 2D may be lower than the first level difference 1D, the third level difference 3D may be lower than the second level difference 2D, and the fourth level difference 4D may be lower than the third level difference 3D (1D>2D>3D>4D). For example, assuming that the 1b-th verify level 1bVr is set higher than the 1a-th verify level 1aVr by 20 mV, the 2b-th verify level 2bVr may be set higher than the 2a-th verify level 2aVr by 15 mV, the 3b-th verify level 3bVr may be set higher than the 3a-th verify level 3aVr by 10 mV, and the 4b-th verify level 4bVr may be set higher than the 4a-th verify level 4aVr by 5 mV. For example, assuming that the 7b-th verify level 7bVr is set lower than the 7a-th verify level 7aVr by 20 mV, the 6b-th verify level 6bVr may be set lower than the 6a-th verify level 6aVr by 15 mV, and the 5b-th verify level 5bVr may be set lower than the 5a-th verify level 5aVr by 10 mV.

Referring to FIG. 6B, the verify levels of some program states may be selectively changed depending on the cycling count of the memory block. When the cycling count of the memory block is less than a cycling reference count, the verify levels of the program states P1 to P4 lower than the first reference voltage 1Rth may be reset, and the verify levels of the program states P5 to P7 higher than the first reference voltage 1Rth may be maintained at previous levels. For example, the first to fourth level differences 1D to 4D of the first to fourth program states P1 to P4 lower than the first reference voltage 1Rth may be equal to each other (1D=2D=3D=4D) or may be different from each other. When the level differences are different from each other, the first level difference 1D may be the highest, the second level difference 2D may be lower than the first level difference 1D, the third level difference 3D may be lower than the second level difference 2D, and the fourth level difference 4D may be lower than the third level difference 3D in the program states P1 to P4 lower than the first reference voltage 1Rth (1D>2D>3D>4D).

Referring to FIG. 6C, the verify levels of some program states among the program states P1 to P4 lower than the first reference voltage 1Rth may be selectively reset depending on the cycling count of the memory block. For example, in the first to fourth program states P1 to P4 lower than the first reference voltage 1Rth, a second reference voltage 2Rth lower than the first reference voltage 1Rth and higher than the 1a-th verify level 1aVr may be further set. For example, when the second reference voltage 2Rth is set between the second and third program states P2 and P3, the verify levels of the first and second program states P1 and P2 lower than the second reference voltage 2Rth among the first to seventh program states P1 to P7 may be selectively reset. For example, the first and second level differences 1D and 2D may be equal to each other (1D=2D), or may be different from each other. When the level differences are different from each other, the first level difference 1D may be the highest, and the second level difference 2D may be set lower than the first level difference 1D.

That is, when the change in verify level is relatively large in low program states among the first to seventh program states P1 to P7, the verify levels of the corresponding program states may be reset, and the verify levels of the remaining program states may be maintained at previous levels.

Referring to FIG. 6D, a third reference voltage 3Rth higher than the first reference voltage 1Rth may be further set in the embodiment described with reference to FIG. 6C. For example, in the fifth to seventh program states P5 to P7 higher than the first reference voltage 1Rth, the third reference voltage 3Rth higher than the first reference voltage 1Rth and lower than the 7a-th verify level 7aVr may be further set. For example, when the third reference voltage 3Rth is set between the fifth and sixth program states P5 and P6, the verify levels of the sixth and seventh program states P6 and P7 higher than the third reference voltage 3Rth among the fifth to seventh program states P5 to P7 may be selectively reset. For example, the sixth and seventh level differences 6D and 7D may be equal to each other (6D=7D), or may be different from each other. When the level differences are different from each other, the seventh level difference 7D may be set higher than the sixth level difference 6D.

That is, when the change in verify level is relatively large in low program states and the change in verify level is relatively large in high program states, among the first to seventh program states P1 to P7, the verify levels of the corresponding program states may be selectively reset, and the verify levels of the remaining program states may be maintained at previous levels.

In the above-described embodiments, the first to third reference voltages 1Rth to 3Rth may be set through a test operation on memory devices. For example, because the memory devices may have different electrical characteristics, a scheme suitable for the corresponding memory device may be applied depending on the results of the test operation.

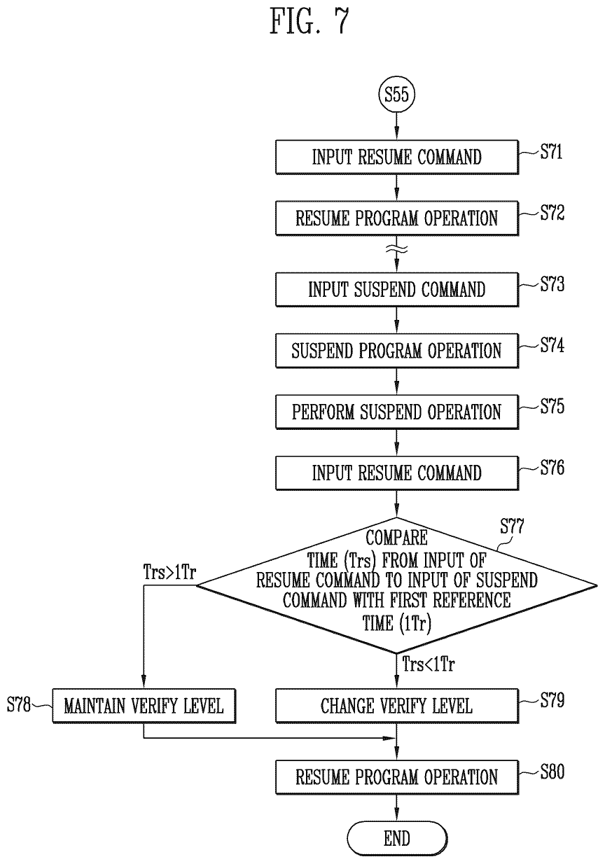

FIG. 7 is a flowchart illustrating a method of operating a memory device according to a second embodiment of the present disclosure.

Referring to FIG. 7, in the second embodiment, after S51 to S55 in the first embodiment, described above with reference to FIG. 5, are performed, a verify level may be maintained or changed using the input times of a resume command and a suspend command. The method of operating the memory device (e.g., 100 of FIG. 2) according to the second embodiment will be described in detail below.

When a resume command is input to the memory device 100 after S55 is performed at S71, the memory device 100 may resume the suspended program operation at S72. When the suspend command is re-input to the memory device 100 after the program operation is resumed at S73, the memory device 100 may suspend the program operation being performed at S74. Between S72 and S73, the program operation resumed at S72 continues to be performed or, alternatively, the program operation resumed at S72 may be completed, and the erase operation and an additional program operation may be performed. Therefore, the program operation suspended at S74 may be the program operation resumed at S72 or the additional program operation.

When the program operation is suspended at S74, the memory device 100 may perform a suspend operation at S75. For example, the controller (e.g., 1200 of FIG. 1) may output the suspend command to the memory device 100, and may then additionally output a command corresponding to the suspend operation. The suspend operation may be a program operation, a read operation or an erase operation.

When a resume command is input to the memory device 100 after the suspend operation is terminated at S76, the control circuit (e.g., 170 of FIG. 2) of the memory device 100 may compare the time Trs from the input of the resume command to the input of the suspend command with a first reference time 1Tr at S77. For example, the control circuit 170 may maintain or change the verify level depending on the time Trs from the performance of the resume operation to the re-input of the suspend command. For example, the control circuit 170 may maintain the verify level when the above-described time Trs is longer than the first reference time 1Tr (Trs>1Tr) at S78.

When the above-described time Trs is shorter than the first reference time 1Tr (Trs<1Tr) at S77, the control circuit 170 may change the verify level at S79. For example, the verify level may decrease when at least one of a verify voltage applied to a selected word line, a bit line voltage applied to bit lines of a selected memory block, and a source line voltage applied to a source line decreases.

When the above-described time Trs is equal to the first reference time 1Tr at S77, the control circuit 170 may be set to perform any one of S78 and S79.

When the verify level is set at S78 or S79, the memory device 100 may resume the suspended program operation at S80.

The case where the time Trs from the performance of the resume operation to the re-input of the suspend command is short in the above-described second embodiment may mean that the suspend operation is frequently performed. This means that the suspend count increases, and thus the method of changing the verify level may be performed through the method described above with reference to FIGS. 6A to 6D.

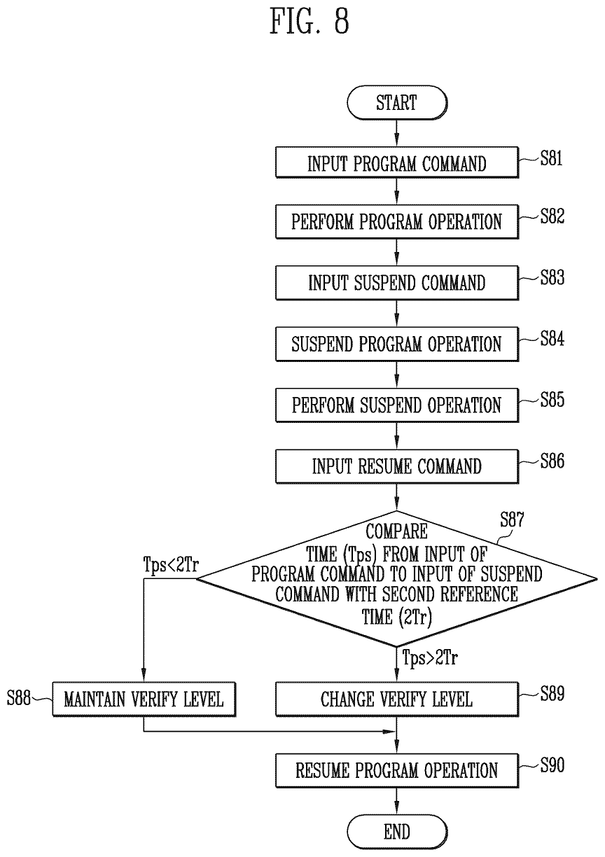

FIG. 8 is a flowchart illustrating a method of operating a memory device according to a third embodiment of the present disclosure.

Referring to FIG. 8, when a program command is input to the memory device at S81, the memory device (e.g., 100 of FIG. 2) may perform a program operation on a selected memory block at S82. For example, the controller (e.g., 1200 of FIG. 1) may output the program command, an address, and data to the memory device 100. The memory device 100 to which the program command, the address, and data output from the controller 1200 are input may select a memory block according to the address, and may program data to the selected memory block in response to the program command.

When a suspend command is input to the memory device 100 while the program operation is being performed on the selected memory block at S83, the memory device 100 may suspend the program operation being performed at S84, and may perform a suspend operation at S85. For example, the controller 1200 may output the suspend command to the memory device 100, and may then additionally output a command corresponding to the suspend operation. The suspend operation may be a program operation, a read operation or an erase operation.

When a resume command is input to the memory device after the suspend operation is terminated at S86, the control circuit (e.g., 170 of FIG. 2) of the memory device 100 may compare the time Tps from the input of the program command to the input of the suspend command with a second reference time 2Tr at S87. For example, the control circuit 170 may maintain or change the verify level depending on the time Tps from the start of the program operation to the input of the suspend command. For example, when the above-described time Tps is shorter than the second reference time 2Tr (Tps<2Tr), the control circuit 170 may maintain the verify level at S88.

At S87, when the above-described time Tps is longer than the second reference time 2Tr (Tps>2Tr), the control circuit 170 may change the verify level at S89. For example, the verify level may decrease when at least one of a verify voltage applied to a selected word line, a bit line voltage applied to bit lines of a selected memory block, and a source line voltage applied to a source line decreases.

When the above-described time Tps is equal to the second reference time 2Tr at S87, the control circuit 170 may be set to perform any one of S88 and S89.

When the verify level is set at S88 or S89, the memory device 100 may resume the suspended program operation at S90.

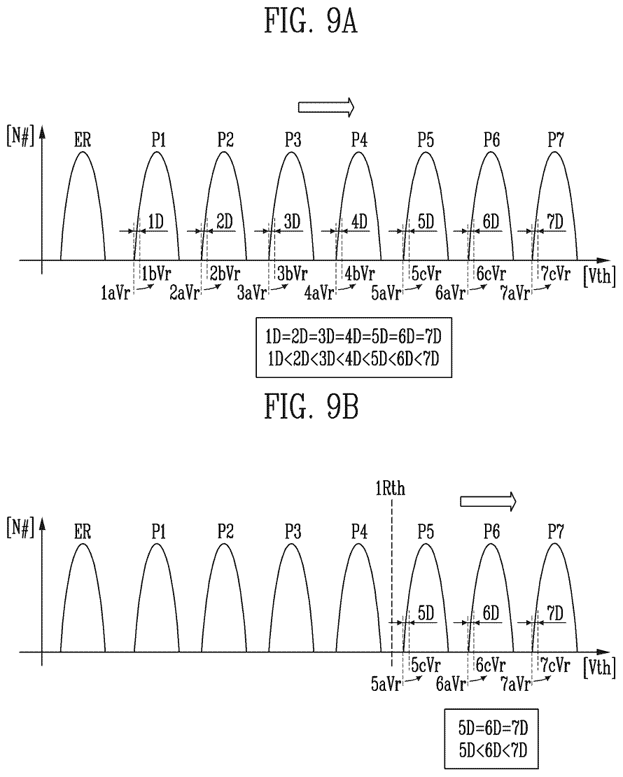

The method of changing the verify level will be described below with reference to FIGS. 9A and 9B.

FIGS. 9A and 9B are diagrams illustrating methods of changing verify levels according to the third embodiment.

Although, in FIGS. 9A and 9B, threshold voltage distributions in a triple-level cell (TLC) scheme are illustrated by way of example, the present embodiment may be applied to schemes other than the triple-level cell (TLC) scheme. In the triple-level cell (TLC) scheme, memory cells may be programmed to an erase state ER or any one of first to seventh program states P1 to P7.

Referring to FIG. 9A, as the time from the performance of a program operation to the input of a suspend command is lengthened, the number of memory cells programmed before a suspend operation is performed may increase. Therefore, the number of memory cells, the retention characteristics of which may be deteriorated, may increase. Due thereto, the verify levels of the first to seventh program states P1 to P7 may decrease. In order to compensate for the decrease in verify level in this way, a 1a-th verify level 1aVr in a first program state P1 may be set higher to a 1b-th verify level 1bVr, a 2a-th verify level 2aVr in a second program state P2 may be set higher to a 2b-th verify level 2bVr, a 3a-th verify level 3aVr in a third program state P3 may be set higher to a 3b-th verify level 3bVr, a 4a-th verify level 4aVr in a fourth program state P4 may be set higher to a 4b-th verify level 4bVr, a 5a-th verify level 5aVr in a fifth program state P5 may be set higher to a 5c-th verify level 5cVr, a 6a-th verify level 6aVr in a sixth program state P6 may be set higher to a 6c-th verify level 6cVr, and a 7a-th verify level 7aVr in a seventh program state P7 may be set higher to a 7c-th verify level 7cVr.

The variable range of the verify levels may be set within a range lower than ½ of the threshold voltage in each of the program states. For example, the 1b-th verify level 1bVr may be set within a range that is higher than the 1a-th verify level 1aVr and lower than ½ of the threshold voltage in the first program state P1. For example, the 7c-th verify level 7cVr may be set within a range that is higher than the 7a-th verify level 7aVr and lower than ½ of the threshold voltage in the seventh program state P7.

The variable widths of respective verify levels in the program states may be equal to or different from each other. For example, the 1a-th verify level 1aVr and the 1b-th verify level 1bVr may have a first level difference 1D, the 2a-th verify level 2aVr and the 2b-th verify level 2bVr may have a second level difference 2D, the 3a-th verify level 3aVr and the 3b-th verify level 3bVr may have a third level difference 3D, the 4a-th verify level 4aVr and the 4b-th verify level 4bVr may have a fourth level difference 4D, the 5a-th verify level 5aVr and the 5c-th verify level 5cVr may have a fifth level difference 5D, the 6a-th verify level 6aVr and the 6c-th verify level 6cVr may have a sixth level difference 6D, and the 7a-th verify level 7aVr and the 7c-th verify level 7cVr may have a seventh level difference 7D. Respective level differences of the program states P1 to P7 may be calculated as values obtained by subtracting low verify levels from high verify levels. For example, the first level difference 1D may be a value obtained by subtracting the 1a-th verify level 1aVr from the 1b-th verify level 1bVr, and the seventh level difference 7D may be a value obtained by subtracting the 7a-th verify level 7aVr from the 7c-th verify level 7cVr.

The first to seventh level differences 1D to 7D may be set equal to each other (1D=2D=3D=4D=5D=6D=7D), or may be different from each other. When the first to seventh level differences 1D to 7D are different from each other, retention characteristics may be deteriorated as the threshold voltages are higher. Accordingly, as the program states are higher, the level differences may be greater.

For example, among the first to seventh level differences 1D to 7D, the first level difference 1D may be the lowest, and the seventh level difference 7D may be the highest (1D<2D<3D<4D<5D<6D<7D). For example, assuming that the 1b-th verify level 1bVr is set higher than the 1a-th verify level 1aVr by 5 mV and the 7c-th verify level 7cVr is set higher than the 7a-th verify level 7aVr by 20 mV, the remaining verify levels, that is, the 2b-th to 4b-th verify levels 2bVr to 4bVr and the 5c-th and 6c-th verify levels 5cVr and 6cVr may be set to have stepwise differences between 5 mV and 20 mV.

Referring to FIG. 9B, the retention characteristics of memory cells may be further degraded in memory cells having higher program states than in memory cells having lower program states. Accordingly, the verify levels of the fifth to seventh program states P5 to P7 higher than the first reference voltage 1Rth may be set higher, and the verify levels of the remaining program states, that is, the first to fourth program states P1 to P4 may be maintained at previous levels. For example, the fifth to seventh level differences 5D to 7D of the fifth to seventh program states P5 to P7 higher than the first reference voltage 1Rth may be equal to each other (5D=6D=7D) or may be different from each other. When the level differences are different from each other, the fifth level difference 5D may be set to the lowest value, and the seventh level difference 7D may be set to the highest value (5D<6D<7D).

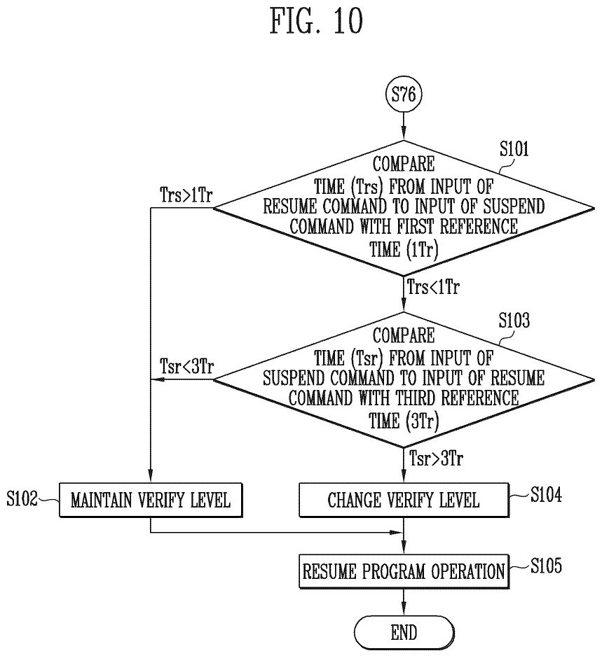

FIG. 10 is a flowchart illustrating a method of operating a memory device according to a fourth embodiment of the present disclosure.

Referring to FIG. 10, in the fourth embodiment, after S71 to S76 in the second embodiment described above with reference to FIG. 7, are performed, the control circuit (e.g., 170 of FIG. 2) of the memory device (e.g., 100 of FIG. 2) may compare the time Trs from the input of the resume command to the input of the suspend command with a first reference time 1Tr at S101. For example, the control circuit 170 may maintain or change the verify level depending on the time Trs from the performance of the resume operation to the re-input of the suspend command. Here, the time at which the resume command is input may be the time at which S71 of FIG. 7 starts, and the time at which the suspend command is re-input may be the time at which S73 of FIG. 7 starts. When the above-described time Trs is longer than the first reference time 1Tr (Trs>1Tr), the control circuit 170 may maintain the verify level at S102.

When the above-described time Trs is shorter than the first reference time 1Tr (Trs<1Tr) at S101, the control circuit (e.g., 170 of FIG. 2) of the memory device 100 may compare the time Tsr from the input of the suspend command to the input of the resume command with a third reference time 3Tr at S103. For example, the control circuit 170 may maintain or change the verify level depending on the time Tsr from the performance of the suspend operation to the re-input of the resume command. For example, when the above-described time Tsr is shorter than the third reference time 3Tr (Tsr<3Tr), the control circuit 170 may maintain the verify level at S102.

When the above-described time Trs is equal to the first reference time 1Tr at S101, the control circuit 170 may be set to perform any one of S102 and S103.

When the above-described time Tsr is longer than the third reference time 3Tr (Tsr>3Tr) at S103, the control circuit 170 may change the verify level at S104. For example, the verify level may decrease when at least one of a verify voltage applied to a selected word line, a bit line voltage applied to bit lines of a selected memory block, and a source line voltage applied to a source line decreases.

When the above-described time Tsr is equal to the third reference time 3Tr at S103, the control circuit 170 may be set to perform any one of S102 and S103.

When the verify level is set at S102 or S104, the memory device 100 may resume the suspended program operation at S105.

S104 in the fourth embodiment indicates the state in which the time Trs from the performance of the resume operation to the re-input of the suspend command is shorter than the first reference time 1Tr (Trs<1Tr) and in which the time Tsr from the input of the suspend command to the input of the resume command is longer than the third reference time 3Tr (Tsr>3Tr). When the time Trs from the performance of the resume operation to the re-input of the suspend command is shorter than the first reference time 1Tr (Trs<1Tr), the number of times a reprogram operation is performed on the memory block may increase. When the time Tsr from the input of the suspend command to the input of the resume command is longer than the third reference time 3Tr (Tsr>3Tr), retention characteristics may be deteriorated. A detailed method of changing the verify level in the fourth embodiment may be performed through the verify level change method, described above with reference to FIGS. 9A and 9B.

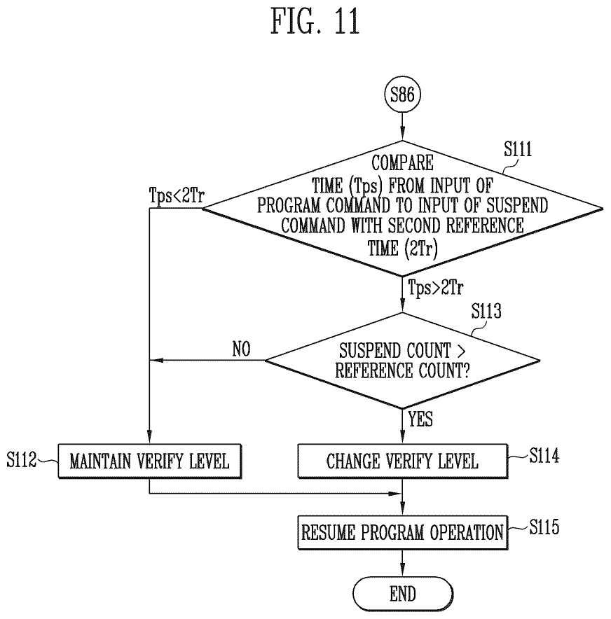

FIG. 11 is a flowchart illustrating a method of operating a memory device according to a fifth embodiment of the present disclosure.

Referring to FIG. 11, in the fifth embodiment, S87 in the third embodiment, described above with reference to FIG. 8, and S57 in the first embodiment, described above with reference to FIG. 5, may be performed. S87 in the third embodiment may correspond to S111 in the fifth embodiment, and S57 in the first embodiment may correspond to S113 in the fifth embodiment. The fifth embodiment will be described in detail below.

In the fifth embodiment, after S81 to S86 in the third embodiment described above with reference to FIG. 8, have been performed, the control circuit (e.g., 170 of FIG. 2) of the memory device (e.g., 100 of FIG. 2) may compare the time Tps from the input of the program command to the input of the suspend command with a second reference time 2Tr at S111. For example, the control circuit 170 may maintain or change the verify level depending on the time Tps from the start of the program operation to the input of the suspend command. For example, when the above-described time Tps is shorter than the second reference time 2Tr (Tps<2Tr), the control circuit 170 may maintain a preset verify level at S112. The verify level may refer to a criterion used to determine whether programming on the memory cells is completed during a verify operation performed in the program operation. For example, the verify level may be changed by at least one of a verify voltage applied to a selected word line, a bit line voltage applied to bit lines of the selected memory block, and a source line voltage applied to a source line.

When the above-described time Tps is longer than the second reference time 2Tr (Tps>2Tr) at S111, the control circuit 170 may compare a suspend count with a reference count at S113. For example, the control circuit 170 may determine whether the suspend count is greater than the reference count. The suspend count may be determined to be the number of suspend commands input to the memory device 100. Therefore, the control circuit 170 may count the number of input suspend commands whenever the suspend command is input.

When the suspend count is less than the reference count (in the case of “No”), the control circuit 170 may maintain a preset verify level at S112.

When the suspend count is greater than the reference count (in the case of “Yes”) at S113, the control circuit 170 may change the verify level at S114. For example, the verify level may be changed when at least one of the verify voltage applied to the selected word line, the bit line voltage applied to the bit lines, and the source line voltage applied to the source line is adjusted.

When the above-described time Tps is equal to the second reference time 2Tr at S111, the control circuit 170 may be set to perform any one of S112 and S113.

When the suspend count is equal to the reference count at S113, the control circuit 170 may be set to perform any one of S112 and S114.

When the verify level is set at S112 or S114, the memory device 100 may resume the suspended program operation at S115.

A detailed method of changing the verify level in the fifth embodiment may be performed through the verify level change method, described above with reference to FIGS. 6A to 6D.

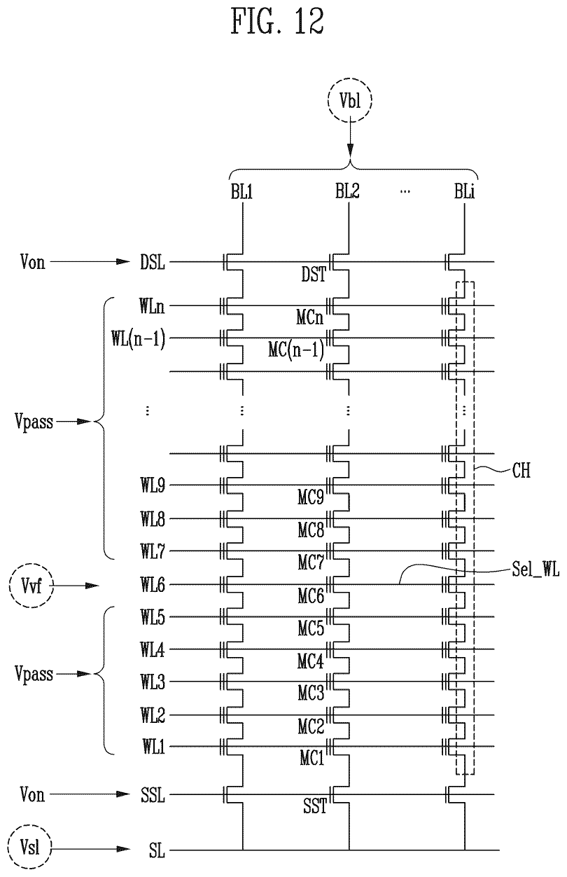

FIG. 12 is a diagram illustrating a method of changing a verify level according to first to fifth embodiments of the present disclosure.

Referring to FIG. 12, the memory block may include source select transistors SST, drain select transistors DST, and first to n-th memory cells MC1 to MCn connected between the source select transistors SST and the drain select transistors DST. The source select transistors SST may electrically connect or disconnect a source line SL and the first memory cells MC1 to or from each other. The drain select transistors DST may electrically connect or disconnect first to i-th bit lines BL1 to BLi and the n-th memory cells MCn to or from each other. Gates of the source select transistors SST may be connected to a source select line SSL, gates of the drain select transistors DST may be connected to a drain select line DSL, and gates of the first to n-th memory cells MC1 to MCn may be connected to first to n-th word lines WL1 to WLn.

A program operation may be performed on memory cells connected to a selected word line Sel_WL among the first to n-th word lines WL1 to WLn. The program operation may include a program voltage apply operation of applying a program voltage to the selected word line Sel_WL and a verify operation of verifying the memory cells. The verify level may be changed in the verify operation.

During the verify operation, a bit line voltage Vbl for precharging the first to i-th bit lines BL1 to BLi to a positive voltage may be applied to the first to i-th bit lines BL1 to BLi and a source line voltage Vsl may be applied to the source line SL. The bit line voltage Vbl may be set to a positive voltage, and the source line voltage Vsl may be set to 0 V or a ground voltage. A pass voltage Vpass for forming a channel CH may be applied to unselected word lines other than the selected word line Sel_WL, and a verify voltage Vvf for verifying the threshold voltages of selected memory cells may be applied to the selected word line Sel_WL. The pass voltage Vpass and the verify voltage Vvf may be positive voltages, and the pass voltage Vpass may have a level higher than that of the verify voltage Vvf. The verify voltage Vvf may be set to various levels depending on the target level. A turn-on voltage Von for turning on the drain select transistors DST and the source select transistors SST may be applied to the drain select line DSL and the source select line SSL. The turn-on voltage Von may be set to a positive voltage.

In the above-described first to fifth embodiments, the verify level may decrease or increase. The verify level may be varied by the verify voltage Vvf, and may also be varied by the potential of the channel CH. For example, when the verify voltage Vvf decreases, the verify level may decrease, whereas when the verify voltage Vvf increases, the verify level may increase. When the potential of the channel CH decreases, the verify level may decrease, whereas when the potential of the channel CH increases, the verify level may increase. The potential of the channel CH may be varied by at least one of the bit line voltage Vbl and the source line voltage Vsl. For example, when at least one of the bit line voltage Vbl and the source line voltage Vsl decreases, the potential of the channel CH may decrease, whereas when at least one of the bit line voltage Vbl and the source line voltage Vsl increases, the potential of the channel CH may increase. Although the bit line voltage Vbl set to the positive voltage decreases, it may decrease to a level higher than 0 V. When the source line voltage Vsl set to the ground voltage decreases, the source line voltage Vsl may be set to a negative voltage.

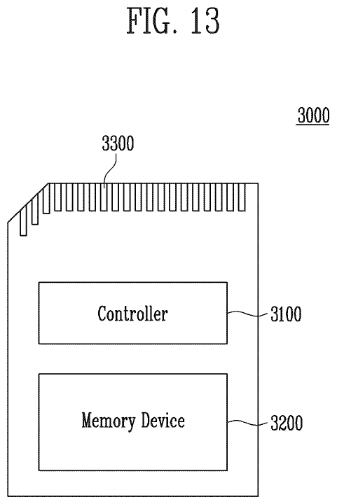

FIG. 13 is a diagram illustrating a memory card system to which a memory system according to an embodiment of the present disclosure is applied.

Referring to FIG. 13, a memory card system 3000 includes a controller 3100, a memory device 3200, and a connector 3300.

The controller 3100 is connected to the memory device 3200. The controller 3100 may access the memory device 3200. For example, the controller 3100 may control a program, a read, or an erase operation of the memory device 3200 or control background operations of the memory device 3200. The controller 3100 may provide an interface between the memory device 3200 and a host. The controller 3100 may run firmware for controlling the memory device 3200. In an embodiment, the controller 3100 may include components, such as a RAM, a processor, a host interface, a memory interface, and an error correction circuit.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include memory cells, and may be configured in the same manner as the memory device 100 illustrated in FIG. 2.

The controller 3100 and the memory device 3200 may be integrated into a single semiconductor device to form a memory card. For example, the controller 3100 and the memory device 3200 may be integrated into a single semiconductor device and may then form a memory card such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), universal flash storage (UFS), or the like.

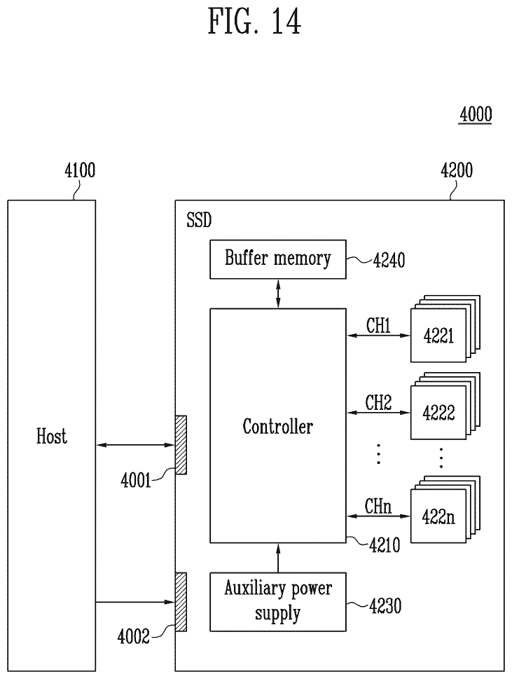

FIG. 14 is a diagram illustrating a solid state drive (SSD) system to which a memory device according to an embodiment of the present disclosure is applied.

Referring to FIG. 14, an SSD system 4000 may include a host 4100 and an SSD 4200. The SSD 4200 may exchange signals with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the signals may be signals based on the interfaces of the host 4100 and the SSD 4200. For example, the signals may be signals defined by at least one of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include cells in which data can be stored. Each of the plurality of memory devices 4221 to 422n may be configured in the same manner as the memory device 100 illustrated in FIG. 2.

The auxiliary power supply 4230 may be connected to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board, and may also provide auxiliary power to the SSD 4200.

The buffer memory 4240 functions as a buffer memory of the SSD 4200. For example, the buffer memory 4240 may store data received from the host 4100 or data received from the plurality of memory devices 4221 to 422n or may store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

According to an embodiment the present disclosure, the threshold voltage distribution of memory cells included in a memory device may be improved.

What is claimed is:

1. A memory device, comprising:
a memory block connected to bit lines and a source line;
a peripheral circuit configured to perform a program operation on the memory block; and
a control circuit configured to control the peripheral circuit to perform the program operation on the memory block in response to a program command, control the peripheral circuit to suspend the program operation and perform a suspend operation in response to a suspend command, and control the peripheral circuit to resume the suspended program operation in response to a resume command,
wherein the control circuit is configured to change verify levels corresponding to program states based on the suspend operation.

2. The memory device according to claim 1, wherein the control circuit is configured to change the verify levels depending on a number of times the suspend operation is performed.

3. The memory device according to claim 2, wherein the control circuit is configured to maintain the verify levels when the number of times the suspend operation is performed is less than a first reference count.

4. The memory device according to claim 3, wherein the control circuit is configured to change the verify levels when the number of times the suspend operation is performed is greater than the first reference count.

5. The memory device according to claim 4, wherein the control circuit is configured to increase a verify level corresponding to a program state lower than a first reference voltage among the program states and to decrease a verify level corresponding to a program state higher than the first reference voltage.

6. The memory device according to claim 4, wherein the control circuit is configured to increase a verify level corresponding to a program state lower than a first reference voltage among the program states and to maintain a verify level corresponding to a program state higher than the first reference voltage.

7. The memory device according to claim 4, wherein the control circuit is configured to increase a verify level corresponding to a program state lower than a second reference voltage that is set lower than a first reference voltage among the program states and to maintain a verify level corresponding to a program state higher than the second reference voltage.

8. The memory device according to claim 4, wherein the control circuit is configured to increase a verify level corresponding to a program state lower than a second reference voltage that is set lower than a first reference voltage among the program states and to decrease a verify level corresponding to a program state higher than a third reference voltage that is set higher than the first reference voltage.

9. The memory device according to claim 1, wherein the control circuit is configured to change the verify levels depending on a duration of time beginning from input of the resume command and ending with input of a next suspend command.

10. The memory device according to claim 9, wherein the control circuit is configured to maintain the verify levels when the duration of time is longer than a first reference time.

11. The memory device according to claim 10, wherein the control circuit is configured to change the verify levels when the duration of time is shorter than the first reference time.

12. The memory device according to claim 1, wherein the control circuit is configured to change the verify levels depending on a duration of time beginning from input of the program command an ending with input of the suspend command.

13. The memory device according to claim 12, wherein the control circuit is configured to maintain the verify levels when the duration of time is shorter than a second reference time.

14. The memory device according to claim 13, wherein the control circuit is configured to change the verify levels when the duration of time is longer than the second reference time.

15. The memory device according to claim 14, wherein the control circuit is configured to increase the verify levels corresponding to all of the program states.

16. The memory device according to claim 14, wherein the control circuit is configured to increase a verify level corresponding to a program state higher than a first reference voltage among the program states and to maintain a verify level corresponding to a program state lower than the first reference voltage.

17. The memory device according to claim 1, wherein the control circuit is configured to change the verify levels depending on a duration of first time beginning from input of the resume command and ending with input of a next suspend command and a duration of second time beginning from input of the next suspend command an ending with input of a next resume command.

18. The memory device according to claim 17, wherein the control circuit is configured to maintain the verify levels when the duration of the first time is longer than a first reference time and the duration of the second time is shorter than a third reference time.

19. The memory device according to claim 18, wherein the control circuit is configured to change the verify levels when the duration of the first time is shorter than the first reference time and the duration of the second time is longer than the third reference time.

20. The memory device according to claim 1, wherein the control circuit is configured to change the verify levels depending on a duration of second time beginning from input of the program command and ending with input of the suspend command and a number of times the suspend operation is performed.

21. The memory device according to claim 20, wherein the control circuit is configured to maintain the verify levels when the duration of the second time is shorter than a second reference time and the number of times is less than a reference count.

22. The memory device according to claim 20, wherein the control circuit is configured to change the verify levels when the duration of the second time is longer than the second reference time and the number of times is greater than the reference count.

23. The memory device according to claim 1, wherein the peripheral circuit is configured to change the verify levels by changing a verify voltage applied to a selected word line among word lines connected to the memory block.

24. The memory device according to claim 1, wherein the peripheral circuit is configured to change the verify levels by changing a potential of a channel of the memory block.

25. The memory device according to claim 24, wherein the peripheral circuit is configured to adjust a bit line voltage applied to the bit lines to change the potential of the channel.

26. The memory device according to claim 24, wherein the peripheral circuit is configured to adjust a source line voltage applied to the source line to change the potential of the channel.

27. A method of operating a memory device, comprising:
performing a program operation on a memory block;
when a suspend command is input while the program operation is being performed, suspending the program operation and performing a suspend operation;
when a resume command is input after the suspend operation is completed, setting verify levels corresponding to program states of the program operation depending on a number of times the suspend operation is performed; and
resuming the program operation using the set verify levels.

28. The method according to claim 27, wherein, when the number of times is less than a first reference count, the verify levels are maintained at preset levels.

29. The method according to claim 28, wherein, when the number of times is greater than the first reference count, the verify levels are changed.

30. The method according to claim 29, wherein a verify level corresponding to a program state lower than a first reference voltage among the program states is set higher, and a verify level corresponding to a program state higher than the first reference voltage is set lower.

31. The method according to claim 29, wherein a verify level corresponding to a program state lower than a first reference voltage among the program states is set higher, and a verify level corresponding to a program state higher than the first reference voltage is maintained.

32. The method according to claim 29, wherein a verify level corresponding to a program state lower than a second reference voltage that is set lower than a first reference voltage among the program states is set higher, and a verify level corresponding to a program state higher than the second reference voltage is maintained.

33. The method according to claim 29, wherein a verify level corresponding to a program state lower than a second reference voltage that is set lower than a first reference voltage among the program states is set higher, and a verify level corresponding to a program state higher than a third reference voltage that is set higher than the first reference voltage is set lower.
